(19) United States
(12) Patent Application Publication
(10) Pub. No.: US 2023/0352383 A1
(43) Pub. Date: Nov. 2, 2023

(54) Multilayer Cores, Variable Width Vias, and Offset Vias

(71) Applicant: Avago Technologies International Sales Pte. Limited., Singapore (SG)

(72) Inventors: Dharmendra Saraswat, Foothill Ranch, CA (US); Arun Ramakrishnan, Lake Forest, CA (US); Sam Zhao, Irvine, CA (US); Sam Karikalan, Ladera Ranch, CA (US); Mayank Mayukh, Fort Collins, CO (US); Liming Tsau, Irvine, CA (US); Reza Sharifi, Irvine, CA (US)

(21) Appl. No.: 17/732,954

(22) Filed: Apr. 29, 2022

(51) Int. Cl. H01L 21/48; H05K 3/42; H05K 1/02; H05K 3/46; H01L 23/498

(52) U.S. Cl. CPC H01L 23/49822; H01L 21/4857; H05K 1/0298; H05K 3/429; H05K 3/4602

(57) ABSTRACT

Novel tools and techniques are provided for implementing a semiconductor package or a chip package, and more particularly, for implementing a semiconductor package or a chip package including a core or a multilayer core having one or more variable width vias or one or more offset vias. In various embodiments, an apparatus includes a substrate. The substrate includes a core. The core may include one or more vias extending through the core. At least one via of the one or more vias includes a cross-section that varies along a length of the at least one via as the via extends through the core. The cross-section of the via may vary based on at least one of varying a width of the at least one via or offsetting a first portion of the at least one via from a second portion of the at least one via.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods, systems, and apparatuses for implementing a semiconductor package or a chip package, and more particularly to methods, systems, and apparatuses for implementing a semiconductor package or a chip package including a core or a multilayer core having one or more variable width vias or one or more offset vias.

### BACKGROUND

Chip packages are ever increasing in size requiring thicker cores (e.g., the dielectric material or dielectric layer of a substrate) to control package warpage. However, having thicker cores in chip packages results in longer core vias (e.g., plated through holes (“PTHs”)) extending through the cores of the chip packages. There are several disadvantages with having longer core vias. Longer core vias cause larger impedance variations as electrical signals travel through the chip package. This in turn results in higher return loss and eventual degradation of signal integrity. In addition, thicker cores with longer core vias cause resonance in insertion loss plots at frequencies which fall in the bandwidth of interest of todays high-speed Serializer/Deserializers (“SerDes”) and cannot be rectified with available organic structure technology.

Hence, there is a need for more robust and scalable solutions for implementing semiconductor packages and chip packages. Thus, methods, systems, and apparatuses for implementing semiconductor packages or chip packages including a core or a multilayer core having one or more variable width vias or one or more offset vias are provided.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIGS. 1A and 1B are schematic cross-sectional views of a substrate of a semiconductor or chip module comprising a multilayer core, in accordance with various embodiments;

FIG. 1C is a top view of a substrate of a semiconductor or chip module, in accordance with various embodiments;

FIGS. 2A-2D are schematic cross-sectional views of a substrate of a semiconductor or chip module comprising a variable width via, in accordance with various embodiments;

FIGS. 3A and 3B are schematic cross-sectional views of a substrate of a semiconductor or chip module comprising a multilayer core layer and a variable width via, in accordance with various embodiments;

FIGS. 4A and 4B are schematic cross-sectional views of a substrate of a semiconductor or chip module comprising at least two variable width vias, in accordance with various embodiments;

FIGS. 5A and 5B are schematic cross-sectional views of a substrate of a semiconductor or chip module comprising an offset via, in accordance with various embodiments;

FIGS. 6A and 6B are schematic cross-sectional views of a substrate of a semiconductor or chip module comprising a multilayer core and an offset diameter via, in accordance with various embodiments;

FIGS. 7A and 7B are schematic cross-sectional views of a substrate of a semiconductor or chip module comprising at least two offset vias, in accordance with various embodiments; and

FIG. 8 is a flow diagram of a method of manufacturing a substrate of a semiconductor or chip module comprising a variable width via or an offset via, in accordance with various embodiments.

### DETAILED DESCRIPTION OF EMBODIMENTS

Various embodiments provide tools and techniques for implementing semiconductor packages or chip packages including a multilayer core and/or a core having one or more variable width vias or one or more offset vias.

In a first aspect, an apparatus including a substrate is provided. The substrate might be a substrate of a printed circuit board (“PCB”), a substrate of an integrated circuit package (e.g., ball grid array (BGA) package, a pin grid array (PGA) package, or other integrated circuit package type that includes a substrate), and/or any other substrate upon which elements of a semiconductor or chip module are fabricated or attached. The substrate includes a core comprising one or more vias extending through the core. The one or more vias may extend along an axis normal to a plane defined by a planar surface of the core. At least one via of the one or more vias has a cross-section that varies along a length of the at least one via as the at least one via extends through the core. In some instances, the cross-section of the at least one via varies based on at least one of varying a width of the at least one via or offsetting a first portion of the at least one via from a second portion of the at least one via.

In some embodiments, varying the width of the at least one via comprises at least one of a middle portion of the at least one via of the one or more vias having a greater width than at least one of a top portion or a bottom portion of the at least one via. At least one of the top portion and the bottom portion of the at least one via might have a same width. Alternatively, at least one of the top portion and the bottom portion of the at least one via have a different width.

In some instances, the one or more vias comprise at least one pair of vias. A first cross-section of a first via of the pair of vias varies along a first length of the first via based on a varying a first width of the first via and a second cross-section of a second via of the pair of vias varies along a second length of the second via based on varying a second width of the second via. In some instances, the first width and the second width may be a same width. Alternatively, the first width and the second width may be a different width. In various embodiments, a first middle portion of the first via of the pair of vias has a greater width than at least one of a first top portion or a first bottom portion of first via and a second middle portion of the second via of the pair of vias has a greater width than at least one of a second top portion or a second bottom portion of the second via.

In various embodiments, the one or more vias comprise at least one pair of vias. A first cross-section of a first via of the pair of vias varies along a first length of a first via of the pair of vias based on offsetting a first portion of the first via from a second portion of the first via and a second cross-section of a second via of the pair of vias varies along a second length of a second via of the pair of vias based on offsetting a first portion of the second via from a second portion of the second via. The second portion of the first via is offset toward the second portion of the second via and the second portion of the second via is offset toward the second portion of the first via. In some instances, the second portion of the first via is a first middle portion of the first via and the second portion of the second via is a second middle portion of the second via and the first middle portion of the first via is offset toward the second middle portion of the second via and the second middle portion of the second via is offset toward the first middle portion of the first via. The first middle portion of the first via may be a same length as the second middle portion of the second via.

In another aspect, a semiconductor device is provided. The semiconductor device includes a substrate comprising two or more core layers. Each core layer is stacked on top of or below another core layer of the two or more core layers. Each core layer may be stacked along an axis normal to a plane defined by a planar surface of each of the two or more core layers. Each core layer includes at least one drill hole. At least one first drill hole of at least one first core layer electrically connects with at least one other drill hole of at least one other core layer to form a via through the two or more core layers. The via has a cross-section that varies along a length of the via as the via extends through the two or more core layers. The cross-section of the via varies based on at least one of having a first width of at least one first drill hole different from a second width of the at least one other drill hole or offsetting a first portion of the at least one first drill hole from a second portion of the at least other drill hole.

In various cases, the at least one first core layer of the two or more core layers comprises a different thickness from the at least one other core layer. The at least one first core layer of the two or more core layers may be formed from a material with a different dielectric coefficient than the at least one other core layer. In some examples, the two or more core layers comprise three core layers and a thickness of each core layer of the three core layers is in the range of 385 micrometers to 435 micrometers.

In some embodiments, the two or more core layers comprise one or more top core layers, one or more middle core layers, and one or more bottom core layers. Varying the cross-section along the length of the via comprises having a larger middle width of one or more first middle drill holes of the one or more middle core layers than a bottom width of one or more bottom drill holes of the one or more bottom core layers or a top width of one or more top drill holes of the one or more top core layers. The one or more middle drill holes, the one or more bottom drill holes, and the one or more top drill holes electrically connect together to form the via extending through the two or more core layers. In some cases, the bottom width of the one or more bottom drill holes of the one or more bottom core layers is the same as the top width of the one or more top drill holes of the one or more top core layers. Alternatively, in other cases, the bottom width of the one or more bottom drill holes of the one or more bottom core layers is different than the top width of the one or more top drill holes of the one or more top core layers.

In various instances, each core layer comprises a pair of drill holes. A first drill hole of a first pair of drill holes of the at least one first core layer electrically connects with a first other drill hole of a second pair of drill holes of the at least one other core layer to form a first via through the two or more core layers. A first cross-section of the first via varies based on at least one of having a first width of the first drill hole different from a first other width of the first other drill hole or offsetting the first drill hole from the first other drill hole. A second drill hole of the first pair of drill holes of the at least one first core layer electrically connects with a second other drill hole of the second pair of drill holes of the at least one other core layer to form a second via through the two or more core layers. A second cross-section of the second via varies based on at least one of having a second width of the second drill hole different from a second other width of the second other drill hole or offsetting the second drill hole from the second other drill hole. When the first drill hole is offset from the first other drill hole and the second drill hole is offset from the second other drill hole, the first drill hole is offset toward the second drill hole and the second drill hole is offset toward the first drill hole. When the first drill hole is offset from the first other drill hole and the second drill hole is offset from the second other drill hole, the first drill hole is electrically connected to the first other drill hole using a first conductive metal running along a first parallel axis parallel to the plane defined by the planar surface of each of the two or more core layers, and wherein the second drill hole is electrically connected to the second other drill hole using a second conductive metal running along a second parallel axis parallel to the plane defined by the planar surface of each of the two or more core layers.

In yet another aspect, a method of manufacturing a variable width via or offset via is provided. The method includes forming at least one first core layer of a core comprising at least one first drill hole. The method continues with forming at least one other core layer of the core comprising at least one other drill hole. The at least one other core layer is layered on top of or below the at least one first core layer along an axis normal to a plane defined by a planar surface of the at least one first core layer. The method further includes electrically coupling the at least one first drill hole with the at least one other drill hole to create a via through the core. The via has a cross-section that varies along a length of the via as the via extends through the core. The cross-section of the via varies based on at least one of having a first width of at least one first drill hole different from a second width of the at least one other drill hole or offsetting a first portion of the at least one first drill hole from a second portion of the at least other drill hole.

In the following description, for the purposes of explanation, numerous details are set forth to provide a thorough understanding of the described embodiments. It will be apparent to one skilled in the art, however, that other embodiments may be practiced without some of these details. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

Similarly, when an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

Furthermore, the methods and processes described herein may be described in a particular order for ease of description. However, it should be understood that, unless the context dictates otherwise, intervening processes may take place before and/or after any portion of the described process, and further various procedures may be reordered, added, and/or omitted in accordance with various embodiments.

Unless otherwise indicated, all numbers used herein to express quantities, dimensions, and so forth should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically stated otherwise.

Additionally, it should be understood that spatial descriptions (e.g., “above,” “below,” “up,” “left,” “right,” “down,” “top,” “bottom,” “middle,” “vertical,” “horizontal,” etc.) used herein are for purposes of illustration only, and that practical implementations of the structures described herein can be spatially arranged in any orientation or manner.

In conventional semiconductor or chip packages, one or more vias may extend through a single layer core of the semiconductor or chip package. The one or more vias (e.g., a plated through hole (“PTH”) via) are electrically conductive openings through a core of the semiconductor or chip package through which an electrical signal may pass. The one or more vias pass one or more electrical signals between different parts of the semiconductor or chip package separated by the single layer core. Conventionally, the one or more vias that extend through the single layer core of the semiconductor or chip package have a same width or a same diameter centered around a vertical axis extending through the center of the via.

The proposed module may be a semiconductor or chip module (e.g., integrated circuit (IC), chip, or other semiconductor device) that provides a multilayer core (e.g., multiple dielectric layers of a substrate), that provides a variable width or a variable diameter via, and/or that provides a first portion of the via that is offset from a second portion of the via. By implementing multilayer cores, variable width vias, and/or offset vias, impedance variations seen by the electrical signal as it travels through the semiconductor or chip package may be minimized. This in turn may improve insertion and return loss of the semiconductor or chip package. Further, by implementing multilayer cores, variable width vias, and/or offset vias, resonance seen in the insertion loss in the frequency bandwidth of interest and cross talk may be minimized or eliminated. Additionally, by implementing a multilayer core, package warpage may be reduced.

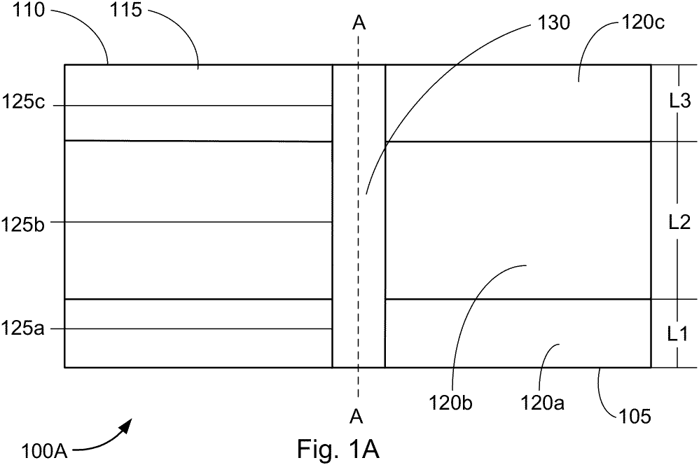

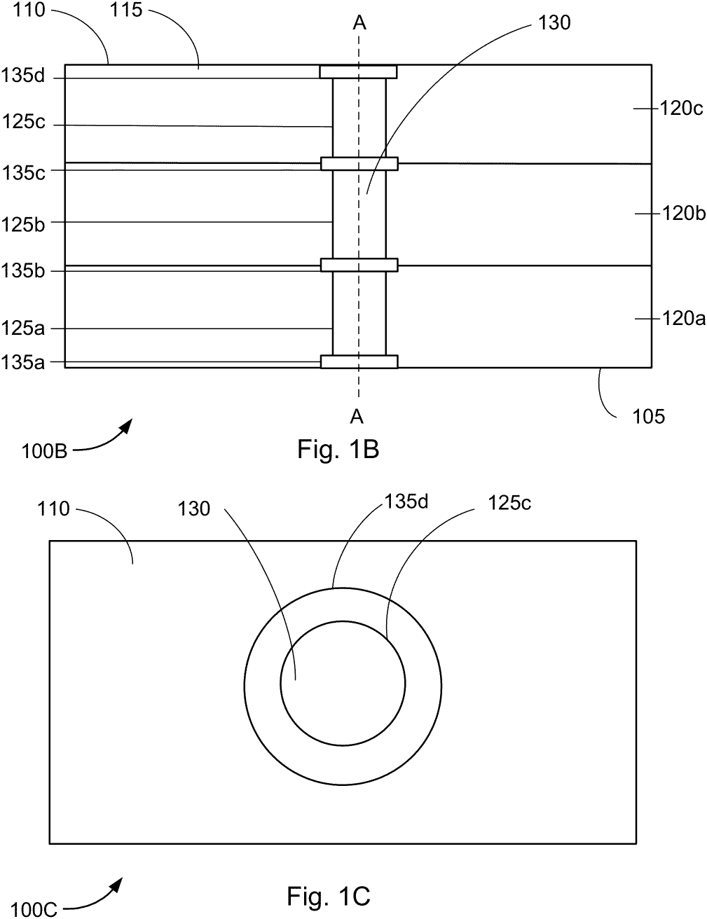

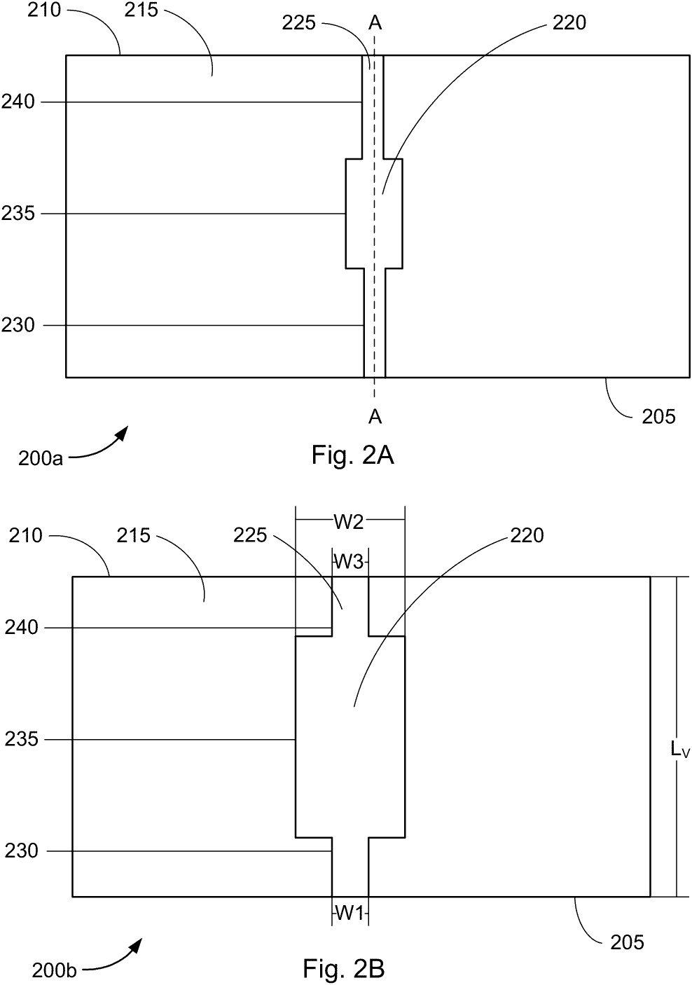

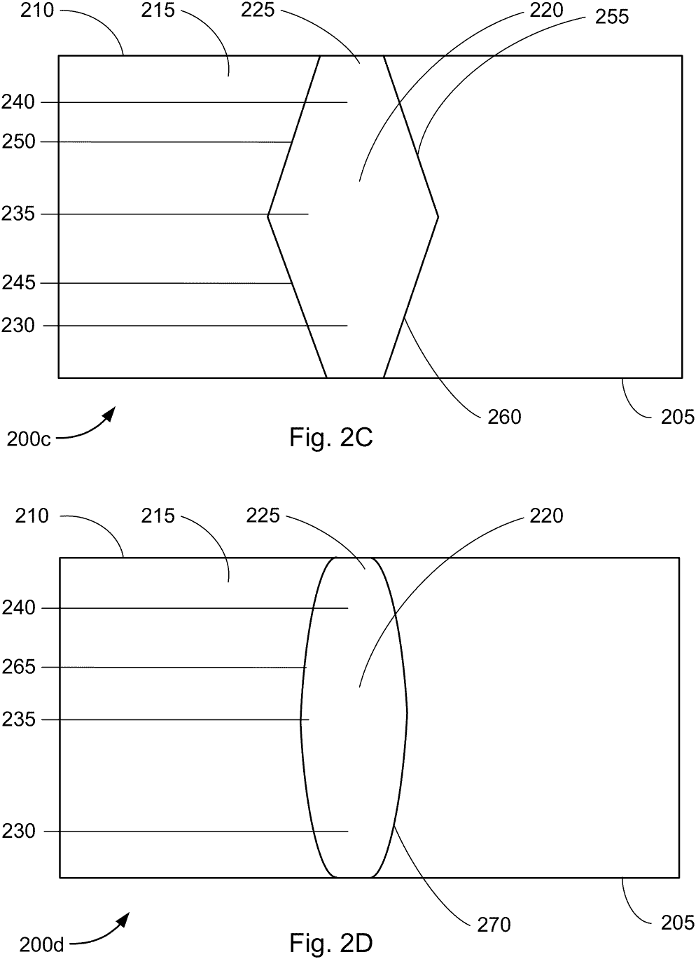

FIGS. 1A and 1B (collectively, FIG. 1) are schematic cross-sectional side views of a substrate 100a and 100b (collectively, substrate 100) of a semiconductor or chip module, in accordance with various embodiments. FIG. 1C is a top view of the substrate 100, in accordance with various embodiments. The semiconductor modules may be an integrated circuit (IC), chip, or other semiconductor device, and/or the like. The substrate 100 may be a substrate of a printed circuit board (“PCB”), a substrate of an integrated circuit package (e.g., ball grid array (BGA) package, a pin grid array (PGA) package, or other integrated circuit package type that includes a substrate), and/or any other substrate upon which elements of a semiconductor or chip module are fabricated or attached. The substrate 100 may have various other components (e.g., components represented in FIGS. 2-7 and/or other components known to persons of ordinary skill in the art) than those depicted in FIG. 1 and is not limited to only the components depicted in FIG. 1.

The substrate 100 may include a first layer 105 and a second layer 110. The first layer 105 and the second layer 110 might be one or more surface layers of the substrate 100. Alternatively, the first layer 105 and the second layer 110 might be one or more inner layers of the substrate 100. The first layer 105 and/or the second layer 110 might have one or more conductive components (e.g., pins, pads, solder balls, etc.) located on the first layer 105 or the second layer 110, may be coated in a conductive coating, may be formed from a conductive material, and/or the like.

A core 115 is located between the first layer 105 and the second layer 110 of the substrate 100. The core 115 of the substrate has one or more dielectric layers 120a, 120b, and 120c (collectively, core layers 120). Although three core layers 120 are shown in FIG. 1, there may be more or less core layers 120 located in substrate 100.

In some cases, each core layer 120a, 120b, and 120c may be formed from a same dielectric material or, in other cases, at least one core layer 120a, 120b, or 120c may be formed from a different dielectric material. In various embodiments, each core layer 120a, 120b, and 120c may be formed from a material with a same dielectric coefficient or, in other cases, at least one core layer 120a, 120b, or 120c may be formed from a material with a different dielectric coefficient.

In some cases, as shown in FIG. 1B, each core layer 120a, 120b, and 120c may be a same or similar thickness. Alternatively, a bottom core layer 120a and a top core layer 120c may be a same or a similar thickness and a middle core layer 120b may be larger (as shown in FIG. 1A) or smaller than the bottom core layer 120a and the top core layer 120c. Alternatively, at least one core layer 120a, 120b, or 120c may be a different thickness from the other core layers. In one embodiment, the thickness of each core layer 120a, 120b, and 120c may be in the range of 385 micrometers to 435 micrometers.

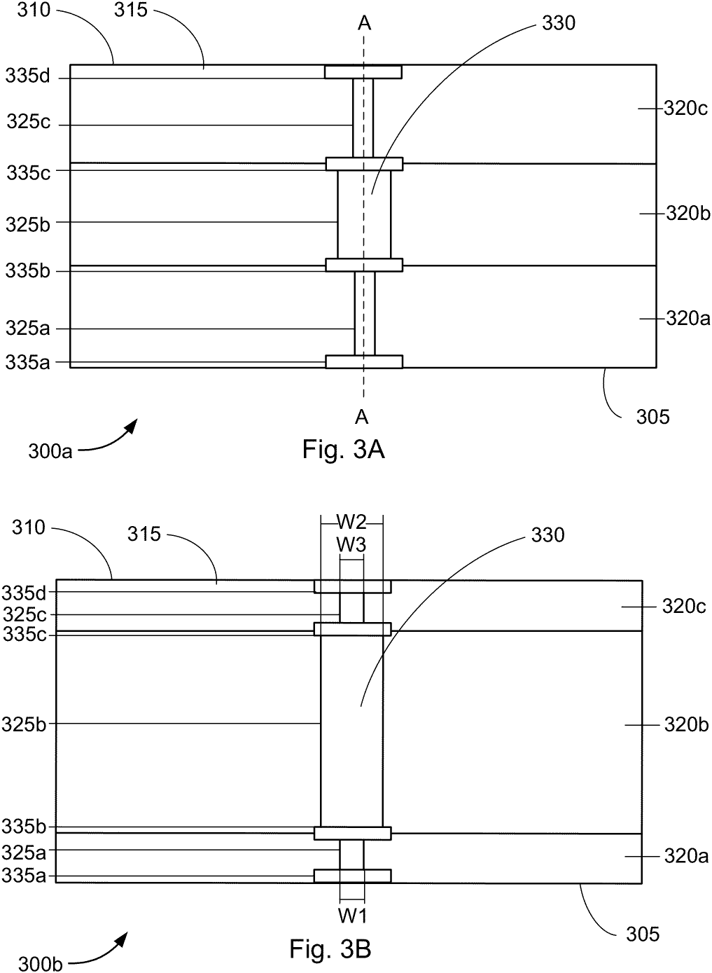

Each core layer 120a, 120b, and 120c may have a corresponding drill hole 125a, 125b, and 125c. Although three drill holes 125a, 125b, and 125c are shown in FIG. 1, there may be more or less drill holes located in each core layer 120a, 120b, and 120c. Each drill hole 125a-125c may have a corresponding length. For example, as shown in FIG. 1A, drill hole 125a may have a length L1, drill hole 125b might have a length L2, and drill hole 125c might have a length L3. Although lengths L1-L3 are shown in FIG. 1A, a person of ordinary skill in the art would know how to identify the lengths of the drill holes in FIG. 1B and the remaining figures (e.g., FIGS. 3, 4B, 6, and 7B). A length of each drill hole 125a, 125b, and 125c may vary based on the thickness or a length of each core layer 120a-120c. For example, if a middle core layer 120b is thicker than layers 120a and 120c, then the length L2 of middle drill hole 125b might be longer than the length L1 of bottom drill hole 125a and the length L3 of top drill hole 125c.

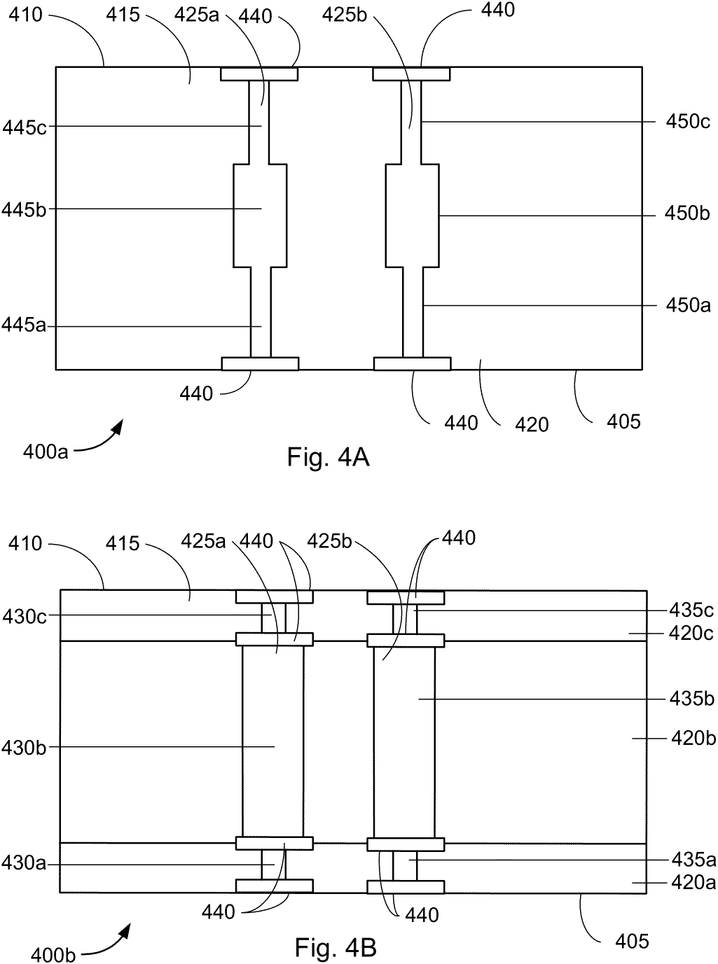

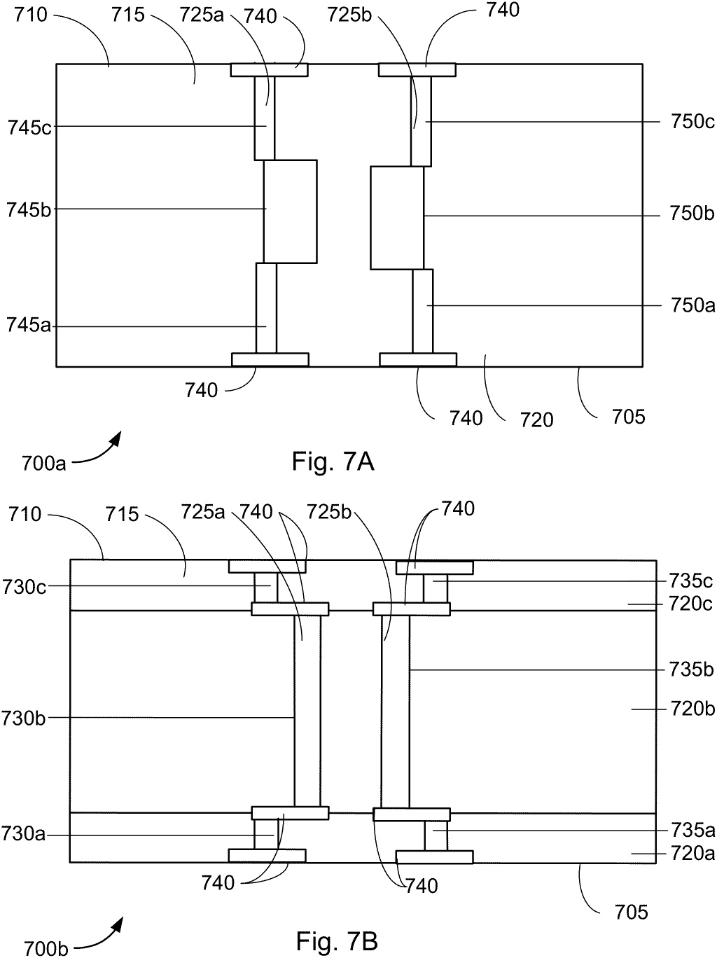

The three drill holes 125a, 125b, and 125c might electrically couple together to form a via 130 through the core layers 120a, 120b, and 120c of the substrate 100. The via 130 may extend along an axis A-A (shown in FIGS. 1A and 1B) which is normal to a plane defined by a planar surface of the core 115. The via 130 may extend completely through the substrate 100 (e.g., a “through” via), may extend through a portion of the substrate 100 from one outer surface (e.g., a “blind” via), or may extend through a portion of the substrate 100 and be completely hidden from external view (e.g., a “buried” via), and/or the like. It should be noted that the core 115 is not limited to only one via 130 and may include more than one via as shown in FIGS. 4 and 7. Additionally, it should also be noted that the various components of the substrate 100, core 115, and via 130 are schematically illustrated in FIG. 1, and that modifications to the various components and other arrangements of the substrate 100, core 120, and via 130 may be possible and in accordance with the various embodiments.

The drill holes 125a, 125b, and 125c may be formed in each core layer 120a, 120b, and 120c by drilling a hole in each core layer 120a, 120b, and 120c, and plating or coating an inner surface of the hole with an electrically conductive material. The drill holes 125a, 125b, and 125c may be plated or coated with a metal such as copper, aluminum, gold, silver, tin, nickel, lead, or a combination of metals/alloy, or may be formed of other electrically conductive material

The via 130 may be formed by forming a first core layer 120a and drilling a first drill hole 125a in the first core layer 120a. Next, a second core layer 120b may be formed on top of the first core layer 120a and a second drill hole 125b may be drilled in the second core layer 120b and electrically coupled to the first drill hole 125a of the first core layer 120a. Additionally, a third core layer 120c may be formed on top of the second core layer 120b and a third drill hole 125c may be drilled in the third core layer 120c and electrically coupled to the second drill hole 125b of the second core layer 120b. The drill holes 125a-125c may be electrically coupled together using an electrically conductive material. The electrically conductive material plating or coating the drill holes 125a, 125b, and 125c forms the via 130 which creates an electrical connection for an electrical signal to travel from the first layer 105 to the second layer 110 of the substrate 100. In some cases, there may be other ways or additional methods to form via 130 and the formation of via 130 is not limited to any particular method of manufacturing a particular core.

In some instances, as shown in FIG. 1B, the first drill hole 125a might optionally include a first via pad 135a and a second via pad 135b, the second drill hole 125b might optionally include the second via pad 135b and a third via pad 135c, and the third drill hole 125c might optionally include the third via pad 135c and a fourth via pad 135d. First via pad 135a is formed on a first layer 105 of the substrate 100 around or near an opening of the first drill hole 125a, second via pad 135b is formed between the first drill hole 125a and the second drill hole 125b, third via pad 135c is formed between the second drill hole 125b and the third drill hole 125c, and the fourth via pad 135d is formed on the second layer 110 of the substrate 100 around or near the opening of the third drill hole 125c.

Via pads 135a-135d are electrically coupled to drill holes 125a-125c and/or via 130. In some instances, vias pads 135a-135d surround an opening of drill holes 125a-125c to electrically couple drill holes 125a-125c together and form via 130. Additionally or alternatively, via pads 135a-135d run along a first parallel axis arranged parallel to the plane defined by the planar surface on top of a corresponding core layer 120a-120c or between two corresponding core layers to electrically couple drill holes 125a-125c together and form via 130. In some examples, via pads 135a-135d may be formed of a metal such as copper, aluminum, gold, silver, tin, nickel, lead, or a combination of metals/alloy, or may be formed of other electrically conductive material.

In some instances, as shown in FIG. 2C for drill hole 125c, via 130, and via pad 135c, the openings of drill holes 125a, 125b, and 125c, the opening of via 130, and/or via pads 135a-135d might be circle-shaped, oval-shaped, square-shaped, rectangular-shaped, and/or the like. Typically, the openings of drill holes 125a, 125b, and 125c and/or the opening of via 130 will be circle-shaped or oval-shaped. The via 130 includes a first portion or bottom portion (e.g., bottom drill hole 125a), a second portion or middle portion (e.g., middle drill hole 125b), and a third portion or top portion (e.g., top drill hole 125c). In some cases, as shown in FIGS. 1A and 1B, a cross-section of the via 130 is constant throughout the three drill holes 125a, 125b, and 125c as the via 130 extends through core 115.

By creating a via 130 using a multilayer core 115, warpage of a semiconductor package and/or chip package may be reduced because a multilayer core 115 provides more stability to substrate 100. Further, by creating each drill hole 125a, 125b, and 125c layer by layer manufacturing processes can use a smaller drill and create smaller cuts in each core layer 120a, 120b, and 120c. This in turn reduces cross-talk because there can be more space between the traces. Additionally, having thinner core layers 120a, 120b, and 120c instead of a thicker one layer core, helps reduces resonance of the core which improves insertion loss and return loss.

Different arrangements of substrate 100, core 115, and via 130 are illustrated below with respect to FIGS. 2-7.

FIGS. 2A-2D (collectively, FIG. 2) are schematic cross-sectional views of a substrate 200a-200d (collectively, substrate 200) of a semiconductor or chip module, in accordance with various embodiments. The substrate 200 may be similar to the substrate 100 of FIG. 1 with a few additional and/or different features. In some cases, functionalities, features, modifications, alterations and/or the like described in FIG. 1 may also be applied to FIG. 2 and vice versa. It should be noted that the various components of the substrate 200 are schematically illustrated in FIG. 2, and that modifications to the various components and other arrangements of the substrate 200 may be possible and in accordance with the various embodiments.

The substrate 200 may include a first layer 205 (e.g., similar to first layer 105 of FIG. 1) and a second layer 210 (e.g., similar to second layer 110 of FIG. 1). A core 215 is located between the first layer 205 and the second layer 210 of the substrate 200. The core 215 may be formed from one or more dielectric materials and/or dielectric layers. In FIG. 2, the core 215 is only one layer, but is not limited to only one layer, as shown in FIGS. 1, 3, 4, 6, and 7.

The core 215 may include a via 220 extending through the core 215. The via 220 may extend along an axis A-A (shown in FIG. 2A) which is normal to a plane defined by a planar surface of the core 215. It should be noted that the core 215 is not limited to only one via 220 and may include more than one via 220 as shown in FIGS. 4 and 7.

The via 220 may be formed in the core 215 by drilling a hole in the core 215 and plating or coating an inner surface of the hole with an electrically conductive material. The electrically conductive material may be copper, aluminum, gold, silver, tin, nickel, lead, or a combination of metals/alloy, or may be formed of other electrically conductive material. The electrically conductive material plating or coating the inner surface of the via 220 forms an electrical connection from the first layer 205 to the second layer 210 of the substrate 200.

In some instances, the opening or drill hole 225 of via 220 might be circle-shaped, oval-shaped, square-shaped, rectangular-shaped, and/or the like. Typically, the opening or drill hole 225 of the via 220 will be circle-shaped or oval-shaped. The via 220 includes a first portion or bottom portion 230, a second portion or middle portion 235, and a third portion or top portion 240. In some cases, the first portion 230 has a first width or a first diameter W1 (shown in FIG. 2B), the second portion 235 has a second width or a second diameter W2 (shown in FIG. 2B), and the third portion 240 has a third width or a third diameter W3 (shown in FIG. 2B). Although the widths (W1—W3) are only shown in FIG. 2B, a person of ordinary skill in the art would know how to identify the widths in FIGS. 2A, 2B, and 2C and the remaining figures (e.g., FIGS. 1 and 3-7). The via 220 is not limited to only three portions and/or three widths and may have more or less than three portions and/or three widths.

In some embodiments, a cross-section of the via 220 might vary along the length Lᵥ of the via 220 as the via 220 extends through the core 215. The cross-section of the via 220 may vary due to varying or variable widths of the via 220. In some cases, the first width (or bottom width) W1 of the bottom portion 230 of the via 220 and the third width (or top width) W3 or the top portion 240 of the via 220 might be a same width or approximately the same width. Alternatively, in other cases, the first width (or bottom width) W1 of the bottom portion of the via 220 and the third width (or top width) W3 of the top portion 240 of the via 220 might be a different width. The second width (or middle width) W2 of the middle portion 235 of the via 220 is different from the first width (or bottom width) W1 of the bottom portion 230 of the via 220 and the third width (or top width) W3 of the top portion 240 of the via 220. The second width (or middle width) W2 of the middle portion 235 of the via 220 is larger or has a greater width than the first width (or top width) W1 of the bottom portion 230 of the via 220 and the third width (or bottom width) W3 of the top portion 240 of the via 220. In various instances, as shown in FIGS. 2C and 2D, the width of the via 220 may vary along a slope (e.g., slopes 245, 250, 255, and/or 260) or a curve (e.g., curves 265 and/or 270) as the length Lᵥ of the via 220 extends through the core 215. In some cases, the width of the via 220 may gradually increase as the via 220 approaches a middle or approximately a middle of the substrate 200, the core 215, and/or the via 220 and gradually decrease as the via 220 approaches an end of the substrate 200, the core 215, and/or the via 220, such that a middle portion 235 of the via 220 is larger than a bottom portion 230 of the via 220 and/or a top portion 240 of the via 220.

In some cases, as shown in FIG. 2A, a length of each of the first portion 230, second portion 235, and third portion 240 of via 220 may be the same or approximately the same. Alternatively, as shown in FIG. 2B, a length of each of the first portion 230, second portion 235, and third portion 240 may vary. For example, as shown in FIG. 2B, the length of the middle portion 235 of the via 220 is shown as being longer than the length of the top portion 240 of the via 220 and the bottom portion 230 of the via 220. Alternatively, in some cases, the length of the middle portion 235 of the via 220 may be shorter than the length of the top portion 240 of the via 220 and the bottom portion 230 of the via 220. Each of the lengths of the first portion 230, the second portion 235, and the third portion 240 of the via 220 may be adjusted or varied to reduce the impedance variation of the substrate 200. In some cases, when core 215 is a multilayer core, the length of the portions of via 220 might vary based on the thickness of each core layer.

It should be noted that the via 220 is not limited to only the shapes, widths, lengths, modifications, or arrangements shown in FIGS. 2A-2D, but may also be various other shapes, widths, lengths, modifications, or arrangements with variable widths, in accordance with the various embodiments. In addition, a person of ordinary skill in the art would understand that the shapes, widths, lengths, modifications, or arrangements shown in FIGS. 2A-2D may also be applied to the substrates shown in FIGS. 1 and 3-7. However, FIGS. 1 and 3-7 are also not limited to the various other shapes, widths, lengths, modifications, or arrangements shown, but may also be various other shapes, widths, lengths, modifications, or arrangements. Each of the shapes, widths, lengths, of the vias shown in FIGS. 1 and 3-7 may be adjusted or arranged to reduce the impedance variation of the substrate substrates or vias.

By varying the width of the via 220 such that the via 225 has a larger width in a middle portion 235 of the via 220, impedance variations seen by the electrical signal as it travels through the substrate 200 by the via 220 may be minimized. For example, by having a bigger diameter in the middle portion 235 of the via 220 and smaller diameter at the two ends (e.g., bottom portion 230 and top portion 240) of the via 220, this arrangement helps to minimize the inductive peak seen in the impedance variation profile of the substrate 200. This in turn may improve insertion and return loss of the substrate 200.

Different arrangements of substrate 200, core 215, and via 220 are illustrated below with respect to FIGS. 3-7.

FIGS. 3A and 3B (collectively, FIG. 3) are schematic cross-sectional views of a substrate 300a and 300b (collectively, substrate 300) of a semiconductor or chip module, in accordance with various embodiments. The substrate 300 may be similar to the substrate 100 of FIG. 1 and/or the substrate 200 of FIG. 2 with a few additional and/or different features. In some cases, functionalities, features, modifications, alterations and/or the like described in FIGS. 1 and 2 may also be applied to FIG. 3 and vice versa. It should be noted that the various components of the substrate 300 are schematically illustrated in FIG. 3, and that modifications to the various components and other arrangements of the substrate 300 may be possible and in accordance with the various embodiments.

The substrate 300 may include a first layer 305 (similar to first layer 105 of FIGS. 1 and 205 of FIG. 2) and a second layer 310 (similar to second layer 110 of FIG. 1 and 210 of FIG. 2). A core 315 is located between the first layer 305 and the second layer 310 of the substrate 300. The core 315 may have one or more layers 320a, 320b, and 320c (collectively, core layers 320) similar to the core layers 120a, 120b, and 120c of FIG. 1. Although three core layers 320 are shown in FIG. 3, there may be more or less core layers 320 located in substrate 300. By having a multilayer core 315, cross talk and return loss of the substrate 300 may be minimized or reduced. In addition, having a multilayer core 315 may increase the rigidity of the substrate 300 and reduce package warpage.

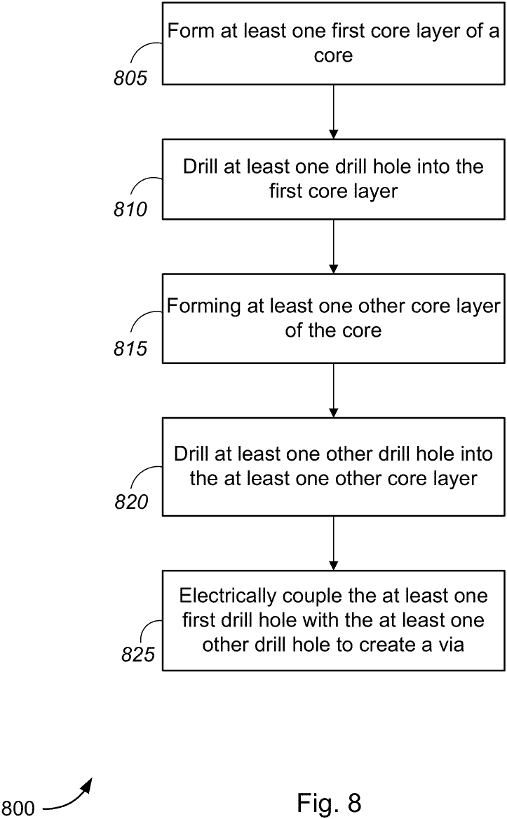

Each core layer 320a, 320b, and 320c may have a corresponding drill hole 325a, 325b, and 325c. Although three drill holes 325a, 325b, and 325c are shown in FIG. 3, there may be more or less drill holes located in each core layer 320a, 320b, and 320c. The three drill holes 325a, 325b, and 325c might electrically couple together to form a via 330 through the core layers 320a, 320b, and 320c. The via 330 may extend along an axis A-A (shown in FIG. 3A) which is normal to a plane defined by a planar surface of the core 315. It should be noted that the core 315 is not limited to only one via 330 and may include more than one via. Each core layer 320, drill hole 325a-325c, and via 330 may be formed in a manner similar to the manufacturing method recited in FIG. 8.

In some instances, the first drill hole 325a might optionally include a first via pad 335a and a second via pad 335b, the second drill hole 325b might optionally include the second via pad 335b and a third via pad 335c, and the third drill hole 325c might optionally include the third via pad 335c and a fourth via pad 335d. Via pads 335a-335d are electrically coupled to drill holes 325a-325c and/or via 330. In some instances, vias pads 335a-235d run along a first parallel axis arranged parallel to the plane defined by the planar surface on top of a corresponding core layer 320a-320c to electrically couple drill holes 325a-325c together and form via 330.

In some instances, the openings of drill holes 325a, 325b, and 325c, the opening of via 330, and/or via pads 335a-335d might be circle-shaped, oval-shaped, square-shaped, rectangular-shaped, and/or the like. The via 330 includes a first portion or bottom portion (e.g., bottom drill hole 325a), a second portion or middle portion (e.g., middle drill hole 325b), and a third portion or top portion (e.g., top drill hole 325c). In some cases, as shown in FIG. 3B, the first portion or first drill hole 325a has a first width or first diameter W1, the second portion or second drill hole 325b has a second width or second diameter W2, and the third portion or third drill hole 325c has a third width or third diameter W3. The via 330 is not limited to only three portions, three drill holes, and/or three widths and may have more or less than three portions, three drill holes, and/or three widths.

In some cases, the first width (or bottom width) W1 of the first drill hole 325a and the third width (or top width) W3 of the third drill hole 325c might be a same width or approximately the same width. Alternatively, in other cases, the first width (or bottom width) W1 of the first drill hole 325a and the third width (or top width) W3 of the third drill hole 325c might be a different width. The second width (or middle width) W2 of the second drill hole 325b is different from the first width (or bottom width) W1 of the first drill hole 325a and the third width (or top width) W3 of the third drill hole 325c. The second width (or middle width) W2 of the second drill hole 325b is larger or has a greater width than the first width (or top width) W1 of the first drill hole 325a and the third width (or bottom width) W3 of the third drill hole 325c. In some cases, the second width (or middle width) W2 of the second drill hole 325b is formed using a larger drill than the drill used to form the first width (or bottom width) W1 of the first drill hole 325a and the third width (or top width) W3 of the third drill hole 325c.

By varying the width of the drill holes 325a, 325b, and 325c and/or via 330 such that the via 330 has a larger width in a middle portion or middle drill hole 325b of the via 330 and by having a multilayer core 315, impedance variations seen by the electrical signal as it travels through the substrate 300 by the via 330 may be minimized. For example, by having a bigger diameter in the middle portion or middle drill hole 325b of the via 330 and smaller diameter at the two ends (e.g., bottom portion or bottom drill hole 325a and top portion or top drill hole 325c) of the via 330 and a multilayer core 315, this arrangement helps to minimize the inductive peak seen in the impedance variation of the substrate 300 and/or via 330. This in turn may improve insertion and return loss of the substrate 300 and/or via 330. Further, by implementing variable width via 330 in a multilayer core 315, resonance seen in the insertion loss in the frequency bandwidth of interest may be minimized or eliminated. Additionally, by implementing a variable width via 330 in a multilayer core 315, package warpage of the chip or semiconductor may be reduced.

Different arrangements of substrate 300, multilayer core 315, and vias 330 are illustrated below with respect to FIGS. 4-7.

FIGS. 4A and 4B (collectively, FIG. 4) are schematic cross-sectional views of a substrate 400a and 400b (collectively, substrate 400) of a semiconductor or chip module, in accordance with various embodiments. The substrate 400 may be similar to the substrate 200 of FIG. 2 and/or 300 of FIG. 3, except instead of only having one via shown, FIG. 4 has at least two vias 425a and 425b. In some cases, functionalities, features, modifications, alterations and/or the like described in FIGS. 1-3 may also be applied to FIG. 4 and vice versa. It should be noted that the various components of the substrate 400 are schematically illustrated in FIG. 4, and that modifications to the various components and other arrangements of the substrate 400 may be possible and in accordance with the various embodiments.

The substrate 400 may include a first layer 405 (similar to first layer 205 of FIG. 2, first layer 205 of FIG. 2, or first layer 305 of FIG. 3) and a second layer 410 (similar to second layer 110 of FIG. 1, second layer 210 of FIG. 2, or second layer 310 of FIG. 3). A core 415 is located between the first layer 405 and the second layer 410 of the substrate 400. The core 415 may have one core layer 420 as shown in FIG. 4A and/or more than one layer (e.g., core layers 420a, 420b, and/or 420c) as shown in FIG. 4B.

The core 415 may have two or more vias 425a and 425b. Each via 425a and 425b may extend along an axis (not shown) which is normal to a plane defined by a planar surface of the core 415. In some cases, as shown in FIG. 4B, each layer 420 of the core 415 may have a corresponding first drill hole (e.g., drill holes 430a, 430b, and 430c) forming first via 425a and a corresponding second drill hole (e.g., drill holes 435a, 435b, and 435c) forming second via 425b. The vias 425a and 425b create an electrical connection from the first layer 405 to the second layer 410 of the substrate 400. Although two vias 425a and 425b are shown in FIGS. 4A and 4B and six drill holes 430a, 430b, and 430c and 435a, 435b, and 435c are shown in FIG. 4B, there may be more or less vias located in core 415 and/or drill holes located in each core layer 420.

In some instances, the vias 425a and 425b might optionally include one or more via pads 440. Via pads 440 are electrically coupled to first drill holes 430a-430c or second drill holes 435a-435c and/or to vias 425a and 425b. In some cases, the via pads 440 might electrically couple the vias 425a and 425b to one or more electrically conductive components (e.g., pins, pads, solder balls, etc.) located on the first layer 405 and the second layer 410, to a conductive coating located on the first layer 405 and the second layer 410, or to the first layer 405 and the second layer 410 formed from a conductive material, and/or the like. In this manner, an electrical connection from the first layer 405 to the second layer 410 of the substrate 400 may be created by vias 425a and 425b.

In some instances, the openings of first drill holes 430a, 430b, and 430c, the openings of second drill holes 435a, 435b, and 435c, the openings of vias 425a and/or 425b, and/or via pads 440 might be circle-shaped, oval-shaped, square-shaped, rectangular-shaped, and/or the like. The first via 425a includes a first portion or bottom portion 445a (e.g., bottom drill hole 430a), a second portion or middle portion 445b (e.g., middle drill hole 430b), and a third portion or top portion 445c (e.g., top drill hole 430c). The second via 425b includes a first portion or bottom portion 450a (e.g., bottom drill hole 435a), a second portion or middle portion 450b (e.g., middle drill hole 435b), and a third portion or top portion 450c (e.g., top drill hole 435c).

In some cases, the first portion 445a or bottom drill hole 430a of the first via 425a and a first portion 450a or bottom drill hole 435a of the second vias 425b has a first width or first diameter W1. The second portion 445b or middle drill hole 430b of the first via 425a and the second portion 450b or middle drill hole 435b of the second via 425b has a second width or second diameter W2. The third portion 445c or top drill hole 430c of the first via 425a and the third portion 450c or top drill hole 435c of the second via 425b has a third width or third diameter W3. The vias 425a and 425b are not limited to only three portions, three widths, and/or three drill holes and may have more or less than three portions, three widths, and/or three drill holes.

In various embodiments, first via 425a and second via 425b might be differential pair vias. The differential pair vias may be routed side-by-side through the core 415 and have the same or approximately the same dimensions. Each via 425a and 425b may carry a signal with a same magnitude and an opposite polarity. For example, first via 425a may be operable to carry an electrical signal with a first polarity and second via 425b may be operable to carry a second electrical signal with an opposite polarity from the first electrical signal. The differential pair vias help lower electromagnetic radiation and pair-to-pair crosstalk.

In some cases, the first width (or bottom width) W1 and the third width (or top width) W3 of each differential via 425a and 425b might be a same width or approximately the same width. Alternatively, in other cases, the first width (or bottom width) W1 and the third width (or top width) W3 of each vias 425a and 425b might be a different width. The second width (or middle width) W2 of each differential via 425a and 425b is different from the first width (or bottom width) W1 and the third width (or top width) W3 of each via 425a and 425b. The second width (or middle width) W2 of each differential via 425a and 425b is larger or has a greater width than the first width (or top width) W1 and the third width (or bottom width) W3 of each via 425a and 425b. By having a larger second width (or middle width) W2, the middle portions 445b and 450b and/or the middle drill holes 430b and 435b of vias 425a and 425b may be brought closer together and/or a distance between the middle portions 445b and 450b and/or the middle drill holes 430b and 435b of vias 425a and 425b may be reduced.

Further advantages may be realized by routing two differential pair vias with variable widths. For example, electromagnetic radiation and pair-to-pair crosstalk may further be minimized as the variable width of the middle portions 445b and 450b or middle drill holes 430b and 435b of the vias 425a and 425b brings the differential vias 425a and 425b closer together. Additionally, impedance variations seen by the electrical signals as they travel through the substrate 400 by the differential vias 425a and 425b may be minimized. For example, by having a bigger diameter in middle portions 445b and 450b or middle drill holes 430b and 435b of the vias 425a and 425b and smaller diameter at the two ends (e.g., bottom portions 445a and 450a or bottom drill holes 430a and 435a and top portions 445c and 450c or top drill holes 430c and 435c) of the differential vias 425a and 425b, this arrangement helps to minimize the inductive peak seen in the impedance variation of the substrate 400. This in turn may improve insertion and return loss of the substrate 400. Further, by implementing variable width differential vias 425a and 425b in a multilayer core 415, as shown in FIG. 4B, resonance seen in the insertion loss in the frequency bandwidth of interest may be minimized or eliminated.

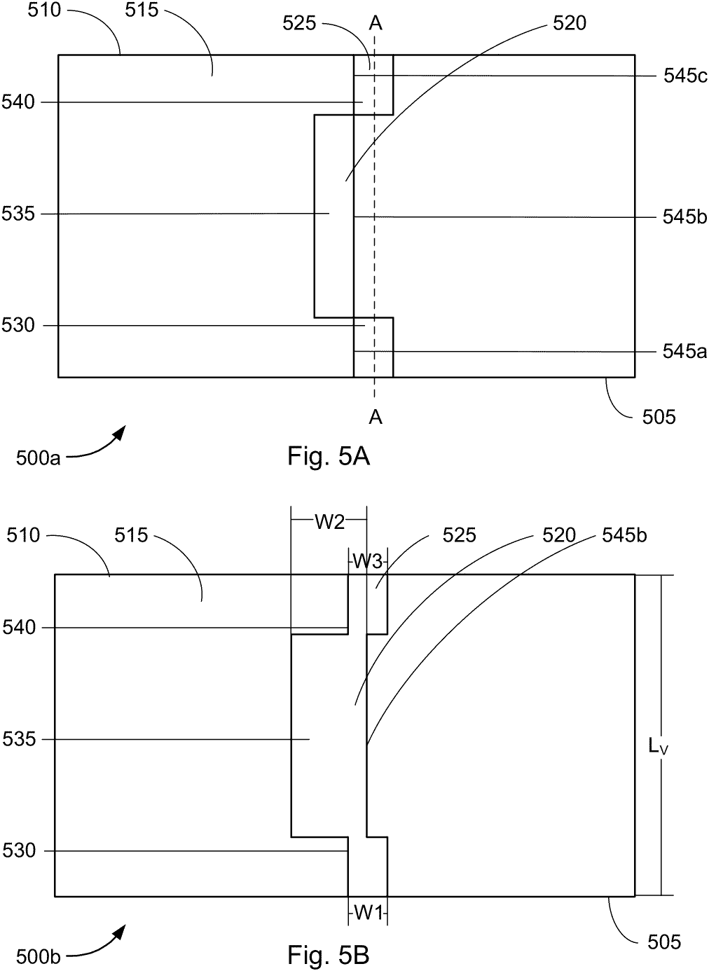

FIGS. 5A and 5B (collectively, FIG. 5) are schematic cross-sectional views of a substrate 500a and 500b (collectively, substrate 500) of a semiconductor or chip module, in accordance with various embodiments. The substrate 500 may be similar to substrate 100 of FIG. 1, substrate 200 of FIG. 2, substrate 300 of FIG. 3, and/or substrate 400 of FIG. 4, except instead of only having a constant width via and/or a variable width via, FIG. 5 has at least one offset via. In some cases, functionalities, features, modifications, alterations and/or the like described in FIGS. 1-4 may also be applied to FIG. 5 and vice versa. It should be noted that the various components of the substrate 500 are schematically illustrated in FIG. 5, and that modifications to the various components and other arrangements of the substrate 500 may be possible and in accordance with the various embodiments.

The substrate 500 may include a first layer 505 (similar to first layer 105 of FIG. 1, first layer 205 of FIG. 2, first layer 305 of FIG. 3, or first layer 405 of FIG. 4) and a second layer 510 (similar to second layer 110 of FIG. 1, second layer 210 of FIG. 2, second layer 310 of FIG. 3, or second layer 410 of FIG. 4). A core 515 is located between the first layer 505 and the second layer 510 of the substrate 500. In FIG. 5, the core 515 is only one layer, but is not limited to only one layer.

The core 515 may include a via 520. The via 520 may extend along an axis A-A (shown in FIG. 5A) which is normal to a plane defined by a planar surface of the core 515. It should be noted that the core 515 is not limited to only one via 520 and may include more than one via 520.

The via 520 may be formed in the core 515 by drilling a hole in the core 515 and plating or coating an inner surface of the hole with an electrically conductive material. An electrical signal is conducted from one electrically conductive component or layer 505 to another electrically conductive component or layer 510 of a substrate 500 by the via 520.

In some instances, the opening or drill hole 525 of via 520 might be circle-shaped, oval-shaped, square-shaped, rectangular-shaped, and/or the like. Typically, the opening or drill hole 525 of the via 520 will be circle-shaped or oval-shaped. The via 520 includes a first portion or bottom portion 530, a second portion or middle portion 535, and a third portion or top portion 540.

In some cases, a length of each of the first portion 530, the second portion 535, and the third portion 540 may be the same or approximately the same. Alternatively, a length of each of the first portion 530, the second portion 535, and the third portion 540 may vary. For example, the length of the middle portion 535 may be longer than the length of the bottom portion 530 and the top portion 540. Alternatively, in some cases, the length of the middle portion 535 may be shorter than the length of the bottom portion 530 and the top portion 540. Each of the lengths of the first portion 530, the second portion 535, and the third portion 540 may be adjusted to reduce the impedance variation of the substrate 500. In some cases, when core 515 is a multilayer core, the length of the portions of via 520 might vary based on the thickness of each core layer.

In some cases, the first portion 530 has a first width or a first diameter W1 (shown in FIG. 5B), the second portion 535 has a second width or a second diameter W2 (shown in FIG. 5B), and the third portion 540 has a third width or a third diameter W3 (shown in FIG. 5B). Although the widths are only shown in FIG. 5B, a person of ordinary skill in the art would know how to identify the widths in the FIG. 5A. The via 520 is not limited to only three portions and/or three widths and may have more or less than three portions and/or three widths.

In some cases, the first width (or bottom width) W1, the second width (or middle width) W2, and the third width (or bottom width) W3 might be a same width or approximately the same width. Alternatively, in other cases, the first width (or bottom width) W1, the second width (or middle width) W2, and the third width (or top width) W3 might be different widths. In some instances, as shown in FIG. 5B, the second width (or middle width) W2 is different from the first width (or bottom width) W1 and the third width (or top width) W3. The second width (or middle width) W2 may be larger or has a greater width than the first width (or bottom width) W1 and the third width (or top width) W3 or the second width (or middle width) W2 may be smaller than the first width (or bottom width) W1 and the third width (or top width) W3.

By varying the width of the via 520 such that the via 520 has a larger width in a middle portion of the via 520, impedance variations seen by the electrical signal as it travels through the substrate 500 by the via 520 may be minimized. For example, by having a bigger diameter in the middle portion 535 of the via 520 and smaller diameter at the two ends (e.g., bottom portion 530 and top portion 540) of the via 520, this arrangement helps to minimize the inductive peak seen in the impedance variation profile of the substrate 500 and/or via 520.

In some embodiments, a cross-section of the via 520 might vary along the length Lᵥ of the via 520 as the via 520 extends through the core 515. The cross-section of the via 520 may vary due to offsetting one or more portions of the via 220. As shown in FIGS. 5A and 5B, the middle portion 535 of the via 520, is offset from the bottom portion 530 and the top portion 540 of the via 520. In some cases, the bottom portion 530 and the top portion 540 of the via 520 are aligned or approximately aligned along a vertical axis A-A extending through a middle of the bottom portion 530 and the top portion 540 of the via 520 while the middle portion 535 is offset from the bottom portion 530 and the top portion 540 of the via 520. In various instances, as shown in FIG. 5A, a second edge 545b of the middle portion 535 might align with a first edge 545a of the bottom portion 530 and a third edge 545c of the top portion 540 of the via 520. In other cases, as shown in FIG. 5B, a second edge 545b of the middle portion 535 might align with a vertical axis (not shown, but shown in FIG. 5A) extending through a middle of the bottom portion 530 and the top portion 540 of the via 520. The amount that the middle portion 535 of the via 520 is offset from the bottom portion 530 and the top portion 540 of the via 520 might vary in order to minimize impedance variations seen by the electrical signal as it travels through the substrate 500 by the via 520.

By offsetting the middle portion 535 of the via 520 from the bottom portion 530 of the via 520 and the top portion 540 of the via 520, impedance variations seen by the electrical signal as it travels through the substrate 500 by the via 520 may be minimized. For example, by offsetting the middle portion 535 of the via 520 from the bottom portion 530 of the via 520 and the top portion 540 of the via 520, this arrangement helps to minimize the inductive peak seen in the impedance variation profile of the substrate 500 and/or via 520. This in turn may improve insertion and return loss of the substrate 500 and/or via 520.

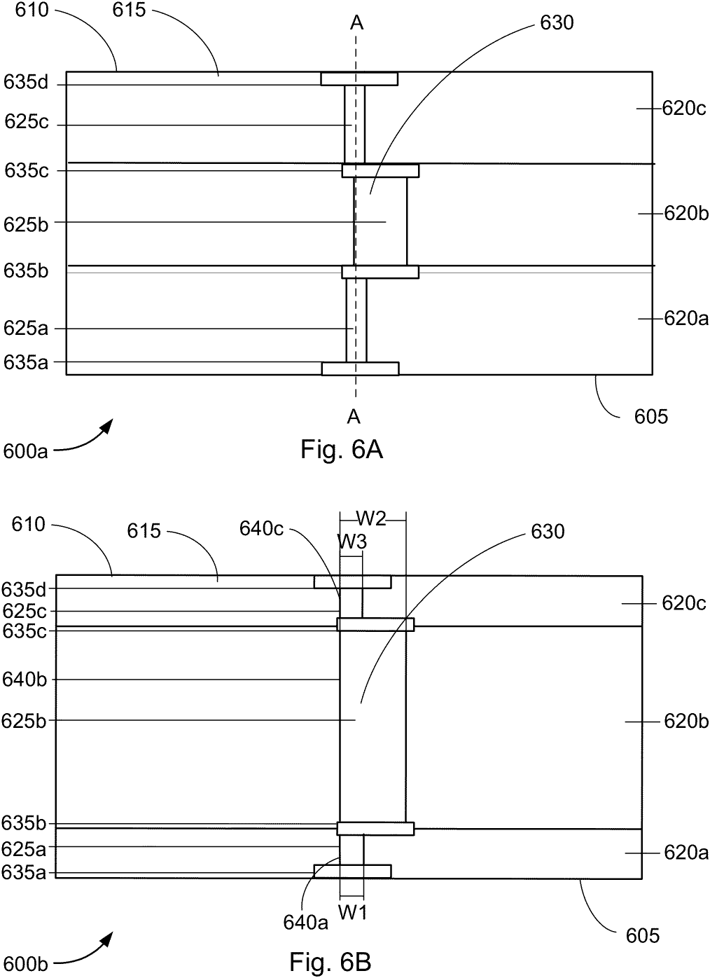

Different arrangements of substrate 500, core 515, and via 520 are illustrated below with respect to FIGS. 6 and 7.

FIGS. 6A and 6B (collectively, FIG. 6) are schematic cross-sectional views of a substrate 600a and 600b (collectively, substrate 600) of a semiconductor or chip module, in accordance with various embodiments. The substrate 600 may be similar to substrate 100 of FIG. 1, substrate 200 of FIG. 2, substrate 300 of FIG. 3, substrate 400 of FIG. 4, and/or substrate 500 of FIG. 5, except instead of only having a constant width via and/or a variable width via, FIG. 6 has at least one offset via within a multilayer core. It should be noted that the various components of the substrate 600 are schematically illustrated in FIG. 6, and that modifications to the various components and other arrangements of the substrate 600 may be possible and in accordance with the various embodiments.

The substrate 600 may include a first layer 605 (similar to first layer 105 of FIG. 1, first layer 205 of FIG. 2, first layer 305 of FIG. 3, first layer 405 of FIG. 4, or first layer 505 of FIG. 5) and a second layer 610 (similar to second layer 110 of FIG. 1, second layer 210 of FIG. 2, second layer 310 of FIG. 3, second layer 410 of FIG. 4, or second layer 510 of FIG. 5). A core 615 is located between the first layer 605 and the second layer 610 of the substrate 600. The core 615 may have one or more layers 620a, 620b, and 620c (collectively, core layers 620). Although three core layers 620 are shown in FIG. 6, there may be more or less core layers 620 located in substrate 600.

Each core layer 620a, 620b, and 620c may have a corresponding drill hole 625a, 625b, and 625c. Although three drill holes 625a, 625b, and 625c are shown in FIG. 6, there may be more or less drill holes located in each core layer 620a, 620b, and 620c. The three drill holes 625a, 625b, and 625c might electrically couple together to form a via 630 through the core layers 620a, 620b, and 620c of the core 615. The via 630 may extend along an axis A-A (shown in FIG. 6A) which is normal to a plane defined by a planar surface of the core 615. It should be noted that the core 615 is not limited to only one via 630 and may include more than one via. Each core layer 620, drill hole 625a-625c, and via 630 may be formed in a manner similar to the manufacturing method recited in FIG. 8.

In some instances, the first drill hole 625a might optionally include a first via pad 635a and a second via pad 635b, the second drill hole 625b might optionally include the second via pad 635b and a third via pad 635c, and the third drill hole 625c might optionally include the third via pad 635c and a fourth via pad 635d. Via pads 635a-635d are electrically coupled to drill holes 625a-625c and/or via 630. In some cases, via pads 635a-635d may form electrical connections or pathways between drill holes 625a-625c. In some instances, vias pads 635a-635d run along a first parallel axis arranged parallel to the plane defined by the planar surface on top of a corresponding core layer 620a-620c or between two corresponding core layer 620a-620c to electrically couple drill holes 625a-625c together and form via 630.

The via 630 includes a first portion or bottom portion (e.g., bottom drill hole 625a), a second portion or middle portion (e.g., middle drill hole 625b), and a third portion or top portion (e.g., top drill hole 625c). In some cases, as shown in FIG. 6B, the first portion or first drill hole 625a has a first width or first diameter W1, the second portion or second drill hole 625b has a second width or second diameter W2, and the third portion or third drill hole 625c has a third width or third diameter W3. The via 630 is not limited to only three portions, three drill holes, and/or three widths and may have more or less than three portions, three drill holes, and/or three widths.

As shown in FIGS. 6A and 6B, the middle drill hole 625b of the via 630, is offset from the bottom drill hole 625a and the top drill hole 625c of the via 630. In some cases, the bottom drill hole 625a and the top drill hole 625c of the via 630 are aligned or approximately aligned along a vertical axis A-A extending through a middle of the bottom drill hole 625a and the top drill hole 625c of the via 630 while the middle drill hole 625b is offset from the bottom drill hole 625a and the top drill hole 625c of the via 630. In some instances, as shown in FIG. 6B, a second edge 640b of the middle drill hole 625b might align with a first edge 640a of the bottom drill hole 625a and a third edge 640c of the top drill hole 625c and a width W2 of the middle drill hole 625b might cause the middle drill hole 625b to be offset from the bottom drill hole 625a and the top drill hole 625c. The amount that the middle drill hole 625b of the via 630 is offset from the bottom drill hole 625a and the top drill hole 625c of the via 630 might vary in order to minimize impedance variations seen by the electrical signal as it travels through the substrate 600 by the via 630.

By offsetting the middle drill hole 625b of the via 630 from the bottom drill hole 625a of the via 630 and the top drill hole 625c of the via 630, impedance variations seen by the electrical signal as it travels through the substrate 600 by the via 630 may be minimized. For example, by offsetting the middle drill hole 625b of the via 630 from the bottom drill hole 625a of the via 630 and the top drill hole 625c of the via 630, this arrangement helps to minimize the inductive peak seen in the impedance variation of the substrate 600 and/or via 630. This in turn may improve insertion and return loss of the substrate 600 and/or via 630. Further, by implementing an offset via 630 in a multilayer core 615, package warpage of the chip or semiconductor may be reduced and resonance may be decreased.

FIGS. 7A and 7B (collectively, FIG. 7) are schematic cross-sectional views of a substrate 700a and 700b (collectively, substrate 700) of a semiconductor or chip module, in accordance with various embodiments. The substrate 700 may be similar to the substrate 500 of FIG. 5 and/or substrate 600 of FIG. 6, except instead of only having one via, FIG. 7 has at least two vias. In some cases, functionalities, features, modifications, alterations and/or the like described in FIGS. 1-6 may also be applied to FIG. 7 and vice versa. It should be noted that the various components of the substrate 700 are schematically illustrated in FIG. 7, and that modifications to the various components and other arrangements of the substrate 700 may be possible and in accordance with the various embodiments.

The substrate 700 may include a first layer 705 (similar to first layer 105 of FIG. 1, first layer 205 of FIG. 2, first layer 305 of FIG. 3, first layer 405 of FIG. 4, first layer 505 of FIG. 5, or first layer 605 of FIG. 6) and a second layer 710 (similar to second layer 110 of FIG. 1, second layer 210 of FIG. 2, second layer 310 of FIG. 3, second layer 410 of FIG. 4, second layer 510 of FIG. 5, or second layer 610 of FIG. 6). A core 715 is located between the first layer 705 and the second layer 710 of the substrate 700. The core 715 may have one core layer 720 as shown in FIG. 7A and/or more than one layer (e.g., core layers 720a, 720b, and/or 720c) as shown in FIG. 7B.

The core 715 may have two or more vias 725a and 725b. Each via 725a and 725b may extend along an axis (not shown) which is normal to a plane defined by a planar surface of the core 715. In some cases, as shown in FIG. 7B, each layer 720 of the core 715 may have a corresponding first drill hole (e.g., drill holes 730a, 730b, and 730c) forming first via 725a and a corresponding second drill hole (e.g., drill holes 735a, 735b, and 735c) forming second via 725b. Although two vias 725a and 725b are shown in FIGS. 7A and 7B and six drill holes 730a, 730b, and 730c and holes 735a, 735b, and 735c are shown in FIG. 7B, there may be more or less vias located in core 715 and/or drill holes located in each core layer 720. In some cases, as shown in FIG. 7B, the three first drill holes 730a, 730b, and 730c might electrically couple together to form a first via 725a through the core layers 720a, 720b, and/or 720c and the three second drill holes 735a, 735b, and 735c might electrically couple together to form a second via 725b through the core layers 720a, 720b, and/or 720c.

In some instances, the vias 725a and 725b might optionally include one or more via pads 740. Via pads 740 are electrically coupled to first drill holes 730a-730c or second drill holes 735a-735c and/or to vias 725a and 725b. In some cases, the via pads 740 might electrically couple the vias 725a and 725b to one or more electrically conductive components (e.g., pins, pads, solder balls, etc.) located on the first layer 705 and the second layer 710, to a conductive coating located on the first layer 705 and the second layer 710, or to the first layer 705 and the second layer 710 formed from a conductive material, and/or the like. In this manner, an electrical connection from the first layer 705 to the second layer 710 of the substrate 700 may be created by vias 725a and 725b.

The first via 725a includes a first portion or bottom portion 745a (e.g., bottom drill hole 730a), a second portion or middle portion 745b (e.g., middle drill hole 730b), and a third portion or top portion 745c (e.g., top drill hole 730c). The second via 725b includes a first portion or bottom portion 750a (e.g., bottom drill hole 735a), a second portion or middle portion 750b (e.g., middle drill hole 735b), and a third portion or top portion 750c (e.g., top drill hole 735c).

In some cases, first via 725a and second via 725b might be a pair of vias (e.g., a pair of differential pair vias). The differential pair vias may be routed side-by-side through the core 715 and have the same or approximately the same dimensions. Each via 725a and second via 725b may carry a signal with a same magnitude and an opposite polarity from the other via. For example, via 725a may be operable to carry an electrical signal with a first polarity and via 725b may be operable to carry a second electrical signal with an opposite polarity from the first electrical signal. The differential pair vias help lower electromagnetic radiation and pair-to-pair crosstalk.

In some embodiments, as shown in FIGS. 7A and 7B, the middle portion 745b or middle drill hole 730b of the first via 725a is offset from a bottom portion 745a or bottom drill hole 730a and the top portion 740c of the via 725a. Additionally, the middle portion 750b or middle drill hole 735b of the second via 725b is offset from a bottom portion 750a or bottom drill hole 735a and the top portion 750c or top drill hole 735c of the via 725b. The middle portion 745b or middle drill hole 730b of the first via 725a is offset toward the middle portion 750b or middle drill hole 735b of the second via 725b. The middle portion 750b or middle drill hole 735b and of the second via 725b is offset toward the middle portion 745b or middle drill hole 730b of the first via 725a.

In some cases, as shown in FIG. 7B, the middle drill hole 730b of the first via 725a is completely offset (e.g., does not overlap) from the bottom drill hole 730a and the top drill hole 730c. The via pads 740 run along a first parallel axis parallel to the plane defined by the planar surface of each of the two or more core layers to electrically couple the middle drill hole 730b of the first via 725a to the bottom drill hole 730a and the top drill hole 730c. Additionally, the middle drill hole 735b of the second via 725b is completely offset (e.g., does not overlap) from the bottom drill hole 735a and the top drill hole 735c. The via pads 740 run along a first parallel axis parallel to the plane defined by the planar surface of each of the two or more core layers to electrically couple the middle drill hole 735b of the first via 725a to the bottom drill hole 730a and the top drill hole 730c.

By offsetting the middle portions 745b and 750b and/or the middle drill holes 730b and 735b of vias 725a and 725b toward each other, the middle portions 745b and 750b and/or the middle drill holes 730b and 735b of vias 725a and 725b may be brought closer together and/or a distance between the middle portions 745b and 750b and/or the middle drill holes 730b and 735b of vias 725a and 725b may be reduced. The amount that the middle portions 745b and 750b and/or the middle drill holes 730b and 735b of vias 725a and 725b is offset from the bottom portion or bottom drill hole and/or the top portion or top drill hole of vias 725a and 725b might vary in order to minimize impedance variations seen by the electrical signal as it travels through the substrate 700 by the vias 725a and 725b.

Additional advantages may be realized by routing two differential pair vias with offset middle portions or offset middle drill holes. For example, electromagnetic radiation and pair-to-pair crosstalk may further be minimized as the offset middle portion or offset middle drill hole of the vias 725a and 725b brings the differential vias 725a and 725b closer together. Additionally, impedance variations seen by the electrical signals as they travel through the substrate 700 by the vias 725a and 725b may be minimized. For example, by offsetting the middle portions 745b and 750c of the vias 725a and 725b from the two ends (e.g., bottom portions 745a and 750a and top portions 745c and 750c) of the vias 725a and 725b, this arrangement helps to minimize the inductive peak seen in the impedance variation of the substrate 700. This in turn may improve insertion and return loss of the substrate 700. Further, by implementing offset vias 725a and 725b in a multilayer core 715, as shown in FIG. 7B, resonance seen in the insertion loss in the frequency bandwidth of interest may be minimized or eliminated.

FIG. 8 is a flow diagram of a method 800 of manufacturing a multilayer core, a variable diameter via, and/or an offset via, in accordance with various embodiments. In some instances, the method 800 might be used to manufacture a multilayer core, a variable diameter via, and/or an offset via, in accordance with FIGS. 1-7. The method 800 may begin, at block 805, by forming at least one first core layer of a core. The core might be a core of a substrate. The substrate might be a printed circuit board (“PCB”). Forming the first core layer of the core may include, without limitation, various additive and/or subtractive manufacturing processes, as known to those skilled in the art. In further examples, manufacturing techniques that are being developed and/or yet to be developed may be utilized to form the first core layer. Thus, it is to be understood that the method 800 is not limited to any particular method of manufacturing a particular core.

The method 800 continues, at block 810, by drilling at least one first drill hole into the first core layer of the core. The at least one first drill might have a first width. The openings of the drill hole might be circle-shaped, oval-shaped, square-shaped, rectangular-shaped, and/or the like.

The method 800 continues, at block 815, by forming at least one other core layer. The at least one other core layer is layered or formed on top of or below the at least one first core layer along an axis normal to a plane defined by a planar surface of the at least one first core layer. Like the first core layer, formation of the other core layer is not limited to any particular manufacturing technique.

At block 820, the method 800 may continue by drilling at least one other drill hole into the other core layer of the core. The at least one other drill hole might have a second width which may be different from or the same as the first width. The openings of drill hole might be circle-shaped, oval-shaped, square-shaped, rectangular-shaped, and/or the like.

The method 800 continues, at block 825, by electrically coupling the at least one first drill hole with the at least one other drill hole to create a via through the core. In some cases, the via has a cross-section that varies along a length of the via as the via extends through the two or more core layers. In some embodiments, the cross-section may vary based on having a width of the at least one first drill hole different from a width of the at least one other drill hole creating a via with a variable width in accordance with FIGS. 2-4. Additionally or alternatively, the cross-section may vary based on offsetting the at least one first drill hole from the at least one other drill hole creating an offset via in accordance with FIGS. 5-7.

The techniques and processes described above with respect to various embodiments may be used to manufacture the substrates 100, 200, 200, 300, 400, 500, 600, and 700, and/or components thereof, as described herein.

While some features and aspects have been described with respect to the embodiments, one skilled in the art will recognize that numerous modifications are possible. For example, the methods and processes described herein may be implemented using hardware components, custom integrated circuits (ICs), programmable logic, and/or any combination thereof. Further, while various methods and processes described herein may be described with respect to particular structural and/or functional components for ease of description, methods provided by various embodiments are not limited to any particular structural and/or functional architecture but instead can be implemented in any suitable hardware configuration. Similarly, while some functionality is ascribed to one or more system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with or without some features for ease of description and to illustrate aspects of those embodiments, the various components and/or features described herein with respect to a particular embodiment can be substituted, added and/or subtracted from among other described embodiments, unless the context dictates otherwise. Consequently, although several embodiments are described above, it will be appreciated that the invention is intended to cover all modifications and equivalents within the scope of the following claims.

What is claimed is:

1. An apparatus comprising:
a substrate, wherein the substrate comprises:
a core comprising:
one or more vias extending through the core, wherein at least one via of the one or more vias has a cross-section that varies along a length of the at least one via as the at least one via extends through the core.

2. The apparatus of claim 1, wherein the one or more vias extend through the core along an axis normal to a plane defined by a planar surface of the core.

3. The apparatus of claim 1, wherein the cross-section of the at least one via varies based on at least one of varying a width of the at least one via or offsetting a first portion of the at least one via from a second portion of the at least one via.

4. The apparatus of claim 3, wherein varying the width of the at least one via comprises at least one of a middle portion of the at least one via of the one or more vias having a greater width than at least one of a top portion or a bottom portion of the at least one via.

5. The apparatus of claim 1, wherein the one or more vias comprise:
at least one pair of vias, wherein a first cross-section of a first via of the pair of vias varies along a first length of the first via based on a varying a first width of the first via and a second cross-section of a second via of the pair of vias varies along a second length of the second via based on varying a second width of the second via.

6. The apparatus of claim 1, wherein the one or more vias comprise:
at least one pair of vias, wherein a first cross-section of a first via of the pair of vias varies along a first length of the first via based on offsetting a first portion of the first via from a second portion of the first via and wherein a second cross-section of a second via of the pair of vias varies along a second length of a second via based on offsetting a first portion of the second via from a second portion of the second via.

7. The apparatus of claim 6, wherein the second portion of the first via is offset toward the second portion of the second via, and wherein the second portion of the second via is offset toward the second portion of the first via.

8. The apparatus of claim 6, wherein the second portion of the first via is a first middle portion of the first via and the second portion of the second via is a second middle portion of the second via, and wherein the first middle portion of the first via is offset toward the second middle portion of the second via and the second middle portion of the second via is offset toward the first middle portion of the first via.

9. The apparatus of claim 8, wherein the first middle portion of the first via is a same length as the second middle portion of the second via.

10. A semiconductor device comprising:
a substrate, wherein the substrate comprises:
two or more core layers, each core layer stacked on top of or below another core layer of the two or more core layers, each core layer comprising:
at least one drill hole, wherein at least one first drill hole of at least one first core layer electrically connects with at least one other drill hole of at least one other core layer to form a via through the two or more core layers, and wherein at the via has a cross-section that varies along a length of the via as the via extends through the two or more core layers.

11. The semiconductor device of claim 10, wherein the at least one first core layer of the two or more core layers comprises a different thickness from the at least one other core layer.

12. The semiconductor device of claim 10, wherein at least one first core layer of the two or more core layers is formed from a material with a different dielectric coefficient than the at least one other core layer.

13. The semiconductor device of claim 10, wherein the cross-section of the via varies based on at least one of having a first width of at least one first drill hole different from a second width of the at least one other drill hole or offsetting a first portion of the at least one first drill hole from a second portion of the at least other drill hole.

14. The semiconductor device of claim 10, wherein the two or more core layers comprise one or more top core layers, one or more middle core layers, and one or more bottom core layers, wherein varying the cross-section along the length of the via comprises having a larger middle width of one or more first middle drill holes of the one or more middle core layers than a bottom width of one or more bottom drill holes of the one or more bottom core layers or a top width of one or more top drill holes of the one or more top core layers, and wherein the one or more middle drill holes, the one or more bottom drill holes, and the one or more top drill holes electrically connect together to form the via extending through the two or more core layers.

15. The semiconductor device of claim 14, wherein the bottom width of the one or more bottom drill holes of the one or more bottom core layers is the same as the top width of the one or more top drill holes of the one or more top core layers.

16. The semiconductor device of claim 14, wherein the bottom width of the one or more bottom drill holes of the one or more bottom core layers is different from the top width of the one or more top drill holes of the one or more top core layers.

17. The semiconductor device of claim 10, wherein each core layer comprises:
a pair of drill holes, wherein a first drill hole of a first pair of drill holes of the at least one first core layer electrically connects with a first other drill hole of a second pair of drill holes of the at least one other core layer to form a first via through the two or more core layers, wherein a first cross-section of the first via varies based on at least one of having a first width of the first drill hole different from a first other width of the first other drill hole or offsetting the first drill hole offset from the first other drill hole, wherein a second drill hole of the first pair of drill holes of the at least one first core layer electrically connects with a second other drill hole of the second pair of drill holes of the at least one other core layer to form a second via through the two or more core layers, wherein a second cross-section of the second via varies based on at least one of having a second width of the second drill hole different from a second other width of the second other drill hole or offsetting the second drill hole from the second other drill hole.

18. The semiconductor device of claim 17, wherein, when the first drill hole is offset from the first other drill hole and the second drill hole is offset from the second other drill hole, the first drill hole is offset toward the second drill hole and the second drill hole is offset toward the first drill hole.

19. The semiconductor device of claim 17, wherein, when the first drill hole is offset from the first other drill hole and the second drill hole is offset from the second other drill hole, the first drill hole is electrically connected to the first other drill hole using a first conductive metal running along a first parallel axis parallel to the plane defined by the planar surface of each of the two or more core layers, and wherein the second drill hole is electrically connected to the second other drill hole using a second conductive metal running along a second parallel axis parallel to the plane defined by the planar surface of each of the two or more core layers.

20. A method comprising:
forming at least one first core layer of a core comprising at least one first drill hole;
forming at least one other core layer of the core comprising at least one other drill hole, wherein the at least one other core layer is layered on top of or below the at least one first core layer along an axis normal to a plane defined by a planar surface of the at least one first core layer;
electrically coupling the at least one first drill hole with the at least one other drill hole to create a via through the core, wherein the via has a cross-section that varies along a length of the via as the via extends through the core.
